(19) United States
(12) Patent Application Publication
(10) Pub. No.: US 2026/0155329 A1
(43) Pub. Date: Jun. 4, 2026

(54) PARTICLE-OPTICAL ARRANGEMENT, FOR EXAMPLE MULTI-BEAM PARTICLE MICROSCOPE, WITH A MAGNET ARRANGEMENT FOR SEPARATING A PRIMARY AND A SECONDARY PARTICLE-OPTICAL BEAM PATH WITH IMPROVED PERFORMANCE

(71) Applicant: Carl Zeiss MultiSEM GmbH, Oberkochen (DE)

(72) Inventors: Dirk ZEIDLER, Oberkochen (DE); Thomas DIETERLE, Murrhardt (DE); Markus KOCH, Neu-Ulm (DE); Thomas SCHMID, Aalen (DE); Felix MENKE, Oberkochen (DE)

(21) Appl. No.: 19/456,713

(22) Filed: Jan. 22, 2026

Related U.S. Application Data
(63) Continuation of application No. PCT/EP2024/025215, filed on Jul. 22, 2024.

(30) Foreign Application Priority Data
Jul. 28, 2023 (DE) 10 2023 120 127.1

(51) Int. Cl. H01J 37/14; H01J 37/12; H01J 37/28

(52) U.S. Cl. CPC H01J 37/14; H01J 37/12; H01J 37/28

(57) ABSTRACT

A particle-optical arrangement provides a primary particle-optical beam path for a plurality of first individual particle beams which, emanating from a multi-beam particle generator, are directed at an object positionable in an object plane of the arrangement, and a secondary particle-optical beam path for a plurality of second individual particle beams which emanate from the object. The particle-optical arrangement has a magnet arrangement having a first magnetic field region through which the primary particle-optical beam path and the second particle-optical beam path pass, for separating the primary particle-optical beam path and the secondary particle-optical beam path from one another. The magnet arrangement also has a second magnetic field region arranged in the primary particle-optical beam path and not arranged in the secondary particle-optical beam path, the second magnetic field region being arranged upstream of the first magnetic field region in relation to the primary particle-optical beam path.

### CROSS-REFERENCE TO RELATED APPLICATIONS

The present application is a continuation of, and claims benefit under 35 USC 120 to, international application No. PCT/EP2024/025215, filed Jul. 22, 2024, which claims benefit under 35 USC 119 of German Application No. 10 2023 120 127.1, filed Jul. 28, 2023. The entire disclosure of each of these applications is incorporated by reference herein.

### FIELD

The disclosure relates to a particle-optical arrangement with an improved beam splitter. Specifically, the disclosure relates to a particle-optical arrangement and for example to a multi-beam particle microscope with a magnet arrangement for separating a primary particle-optical beam path and a secondary particle-optical beam path with improved performance.

### BACKGROUND

With the ongoing development of ever smaller and ever more complex microstructures such as semiconductor components, there is a desire to further develop and optimize planar production techniques and inspection systems for producing and inspecting small dimensions of the microstructures. For instance, the development and production of the semiconductor components typically involve monitoring of the design of test wafers, and the planar production techniques typically involve process optimization for reliable production with high throughput. Moreover, there have been recent demands for an analysis of semiconductor wafers for reverse engineering and for a customized, individual configuration of semiconductor components. Therefore, there is a desire for an inspection mechanism which can be used with high throughput to examine the microstructures on wafers with high accuracy.

Typical silicon wafers used in the production of semiconductor components have diameters of up to 300 mm. Each wafer is usually subdivided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case extends from a few μm to the critical dimensions (CD) of 5 nm, wherein the structure sizes will become even smaller in the near future. In future, structure sizes or critical dimensions (CD) are expected to be less than 3 nm, for example 2 nm, or even less than 1 nm. In the case of the aforementioned small structure sizes, defects on the order of the critical dimensions are to be identified relatively quickly over a relatively large area. For several applications, the desired accuracy of a measurement provided by inspection equipment is even higher, for example by a factor of two or one order of magnitude. For instance, a width of a semiconductor feature is measured with an accuracy of below 1 nm, for example 0.3 nm or even less, and a relative position of semiconductor structures are determined with an overlay accuracy of below 1 nm, for example 0.3 nm or even less.

The MSEM, a multi-beam scanning electron microscope, is a relatively new development in the field of charged particle systems (“charged particle microscopes”, CPMs). For instance, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a multiplicity of individual electron beams, which are arranged in a field or grid. For instance, 4 to 10,000 individual electron beams can be provided as primary radiation, with each individual electron beam being separated from an adjacent individual electron beam by a pitch of 1 to 200 micrometers. By way of example, an MSEM has approximately 100 separate individual electron beams (“beamlets”), which are arranged for example in a hexagonal grid, with the individual electron beams being separated by a pitch of approximately 10 μm. The plurality of charged individual particle beams (primary beams) are focused on a surface of a sample to be examined by way of a common objective lens. For example, the sample can be a semiconductor wafer which is secured to a wafer holder mounted on a movable stage. When the wafer surface is illuminated by the charged primary individual particle beams, interaction products, for example secondary electrons or backscattered electrons, emanate from the surface of the wafer. Their start points generally correspond to those locations on the sample on which the plurality of primary individual particle beams are focused in each case. The amount and the energy of the interaction products generally depend on the material composition and the topography of the wafer surface. The interaction products form a plurality of secondary individual particle beams (secondary beams), which are collected by the common objective lens and, by virtue of a projection imaging system of the multi-beam inspection system, are incident on a detector arranged in a detection plane. The detector comprises several detection regions, each of which may comprise several detection pixels, and the detector acquires an intensity distribution for each of the secondary individual particle beams. An image field of 100 μm×100 μm, for example, is obtained in the process.

A known multi-beam electron microscope comprises a sequence of electrostatic and magnetic elements. At least some of the electrostatic and magnetic elements are adjustable in order to adapt the focus position and the stigmation of the plurality of charged individual particle beams. Such a multi-beam system with charged particles moreover comprises at least one cross-over plane of the primary or the secondary charged individual particle beams. Moreover, such a system comprises detection systems in order to facilitate the adjustment. Such a multi-beam particle microscope comprises at least one beam deflector (“deflection scanner”) for collective scanning of a region of the sample surface via the multiplicity of primary individual particle beams in order to obtain an image field of the sample surface.

What is known as a beam splitter (or alternatively beam separator or beam divider) can be used to separate the particle-optical beam path of the primary beams from the particle-optical beam path of the secondary beams. In this case, separation is implemented using special arrangements of magnetic fields and/or electrostatic fields, for example using a Wien filter.

Imaging aberrations arise quite generally as a result of using particle-optical components. For example, these include field curvature and field astigmatism. Aberrations within the scope of particle-optical imaging, which are to be corrected where possible, can also arise when a beam splitter is used. Ideally, imaging aberrations are avoided or corrected for all individual particle beams. The corrections normally become ever more relevant as image fields become ever more extensive within the scope of particle-optical imaging. An image field can be particularly extensive in the case of multi-beam particle microscopes which operate with a plurality of individual particle beams (multi-image field, so-called mFOV). This is all the more applicable as multi-beam particle microscopes operate with more and more individual particle beams, thus causing the size of the image field to increase again.

As the demands on the imaging quality increase, so do the demands on the multi-beam particle microscope used for imaging. For example, an object plane field curvature is minimized in order to obtain a very good resolution of a multi-beam particle microscope. In a first measure, the electron-optical unit or the charged particle-optical unit of the multi-beam particle microscope is optimized. In a second measure, it has been proposed to use active apparatuses for individual beam correction and for example for focal length adaptation per beam.

Optimizing the electron-optical unit in the course of the first measure also includes optimizing beam splitters. To correct aberrations due to beam splitters of multi-beam particle microscopes, EP 1 668 662 B1 discloses the provision of a further magnetic sector field in the primary path upstream of the actual separating magnetic sector field. Aberrations in the secondary path are corrected by up to three further magnetic sector fields in the secondary path. According to EP 1 668 662 B1 it is possible to correct first-order aberrations in the primary path and also in the secondary path. As the demands on the resolution increase, however, it becomes increasingly desirable to correct higher-order aberrations as well.

An active correction apparatus is known from U.S. Pat. No. 9,153,413 B2. The latter discloses a further beam splitter for multi-beam particle microscopes, in the case of which there is a correction of beam splitter-induced aberrations. The beam splitter operates according to the Wien filter principle. To correct aberrations, alignments or skews of individual particle beams are respectively corrected singly or individually via multi-deflector arrays following the passage through the beam splitter.

Moreover, it has been proposed to use active apparatuses for an individual focal length adaptation for each beam, for example arrays of individually addressable ring electrodes as active parts of micro-individual-lens arrays. The focal length of an individual micro-Einzel-lens has an approximately quadratic dependence on the voltage applied to the respective lens electrode. However, these active apparatuses for correcting the field curvature for each individual particle beam are hard to manufacture and expensive. It is desirable here that each individual micro-correction-apparatus functions perfectly because otherwise this type of correction apparatus is generally not desirable. Moreover, it can be for example challenging to supply each micro-Einzel-lens arrangement with a voltage of the order of more than 50 V, more than 100 V or even more than 400 V. This is because relatively severe insulation issue can arise in the process, and the current active correction apparatuses may have only a very limited service life. Examples of active correction apparatuses are found e.g. in U.S. Pat. Nos. 5,834,783, 6,483,120, 6,903,353, 7,126,141 and 11,145,485.

As more and more individual particle beams and thus larger and larger image fields are used, the active correctors described above can encounter their limits. It is therefore desirable to further improve the electron-optical unit itself. This also includes further improvement of the beam splitter. The demands on active further correction elements may also be limited as a result.

DE 35 32 698 A1 describes an alpha-type electron energy filter intended for use in a TEM. The electron energy filter disclosed is a dispersive energy filter which has a symmetrical construction and overall comprises (or consists of) three deflection regions separated from one another by interspaces. Edge inclinations of the magnetic sectors with respect to the wavefront are disclosed in this specific arrangement.

DE 101 07 910 A1 discloses a particle beam system such as a scanning electron microscope, for example, which has a mirror corrector. The mirror corrector comprises an electrostatic mirror and a magnetic deflector comprising (or consisting of) five sectors. The bottommost or last sector is a splitting sector. The magnetic deflector overall is a direct-vision deflector which is free of dispersion. The influence of trench inclinations on the focusing effect of the magnet arrangement is additionally disclosed. An exit trench of the splitting sector is not inclined.

DE 35 32 699 A1 discloses an omega-type electron energy filter. The overall arrangement is symmetrical. Edges of magnetic sectors may be inclined in this specific arrangement.

U.S. Pat. No. 7,244,949 B2 discloses a beam splitter with a total of three magnetic sectors in the secondary path. The bottommost trench of the splitting sector is not inclined.

### SUMMARY

The disclosure seeks to provide a particle-optical arrangement and for example a multi-beam particle microscope by which beam splitter-induced aberrations which occur in the primary path, for example, can be even better corrected.

The disclosure seeks to further reduce the field inclination and the field astigmatism. At the same time, other imaging aberrations of the second order or higher ought not to be increased in this case.

The aberrations which may typically occur in multi-beam particle microscopes include for example spherical aberrations, astigmatism, coma, field curvature, distortion, chromatic aberrations or dispersion, etc. In the multi-beam particle microscope described in EP 1 668 662 B1, having the beam splitter already briefly described above or the described arrangement of magnetic sector fields or magnetic field regions, imagings of the plurality of the first individual particle beams into the object plane may substantially already overall be substantially stigmatic to a first order and substantially distortion-free to a first order, and moreover dispersion-free. The disclosure of EP 1 668 662 B1 is fully incorporated by reference in the present patent application.

The present disclosure seeks to further improve the performance of the already known beam splitter and thus the performance of multi-beam particle beam systems and, for example, multi-beam particle microscopes.

For this purpose, the aberrations induced by the known beam splitter have been examined more closely, with high-precision measurements having been carried out in order to create a so-called focus map. This has shown that the remaining leading residual error during the particle-optical imaging is often not the field curvature at all, but rather the field inclination. In the case of field inclination, the focal position of first individual particle beams in relation to the (ideal) object plane changes linearly with the distance from the optical axis. In contrast, the focal position changes quadratically with the distance from the optical axis in the case of field curvature. Several compensators for correcting a field inclination have already been proposed in DE 2021 200 799 B3.

Unlike field curvature, for example, the field inclination is a non-rotationally symmetric aberration. A cause of non-rotationally symmetric aberrations in the case of existing beam splitters can be found in the break of symmetry in the case of the beam splitters. An angle (“skew angle”) between the optical axis upon entrance of the primary beams into the beam splitter and the optical axis upon emergence of the primary beams from the beam splitter may contribute to this break of symmetry. Therefore, one possible approach involves changing the design of the beam splitter itself and arranging at least one further magnetic field region in the primary path and eliminating the skew angle, although this can entail further system adaptations.

The present disclosure therefore allows for a different approach. A basic design of the beam splitter or the magnet arrangement having only two sectors or magnetic field regions in the primary path is intended to be maintained in general. At the same time, however, the beam splitter-induced imaging aberrations are intended to be reduced further. In the course of investigations in the context of the disclosure, surprisingly a totally non-intuitive solution took shape which, with only two magnetic field regions in the primary path, allows even leading second-order imaging aberrations, namely field inclination and field astigmatism, to be substantially eliminated or drastically reduced. At the same time, other imaging aberrations are substantially not increased.

According to a first aspect of the disclosure, the latter consequently relates to a particle-optical arrangement for providing a primary particle-optical beam path for a plurality of charged first individual particle beams which, emanating from a multi-beam particle generator, are directed at an object positionable in an object plane of the arrangement, and a secondary particle-optical beam path for a plurality of charged second individual particle beams which emanate from the object, wherein the particle-optical arrangement has a magnet arrangement comprising: a first magnetic field region through which the primary particle-optical beam path and the secondary particle-optical beam path pass, for the separation of the primary particle-optical beam path and the secondary particle-optical beam path from one another; a second magnetic field region arranged in the primary particle-optical beam path and not arranged in the secondary particle-optical beam path, the second magnetic field region being arranged upstream of the first magnetic field region in relation to the primary particle-optical beam path, and the first magnetic field region and the second magnetic field region deflecting the primary particle-optical beam path in different directions;

wherein each magnetic field region has an entrance region for the primary particle-optical beam path with an entrance inclination φ and an exit region for the primary particle-optical beam path with an exit inclination σ, wherein the entrance inclination φ is defined as the angle by which the alignment of the entrance region deviates from the normal to the particle-optical axis Z of the primary particle-optical beam path, and wherein the exit inclination σ is defined as the angle by which the alignment of the exit region deviates from the normal to the particle-optical axis Z of the primary particle-optical beam path, and wherein the exit inclination σ1 of the first magnetic field region deviates from 0°.

In this case, the exit inclination σ1 of the first magnetic field region deviates from 0° intentionally rather than, for instance, randomly owing to an inaccuracy in the alignment. The accuracy with which the exit inclination σ1 of the first magnetic field region can be set is for example +/−0.1° or better, such as +/−0.05° or better.

Using the exit inclination that deviates from 0°, it is possible for aberrations of the magnet arrangement to be reduced significantly further. This is surprising insofar as this geometry is not intuitive at all. Particularly if the magnet arrangement is integrated as beam splitter into a multi-beam particle microscope, this can lead to the situation that a lengthening of the particle-optical axis A of the objective lens non-orthogonally intersects the exit region of the first magnetic field region of the magnet arrangement. The fact that aberrations of the magnet arrangement and also of the multi-beam particle microscope can be significantly reduced in the case of such a geometric arrangement is therefore surprising. What is achievable, for example, is a reduction of a beam splitter-induced field inclination and of a beam splitter-induced field astigmatism approximately by a factor of 6 in each case compared with a magnet arrangement in which the exit inclination σ1 of the first magnetic field region is 0° or in the case of a multi-beam particle microscope in which a lengthening of the particle-optical axis A of the objective lens orthogonally intersects the exit region of the first magnetic field region. By way of example, it is possible to reduce a field inclination δ in an object plane to δ≤0.05°, such as δ≤0.04°—specifically without an additional active corrector such as a multi-stigmator arrangement, for example, being used or being desirable for this purpose. In addition, the resolution of a multi-beam particle microscope can also be significantly improved by the disclosure, specifically approximately by a factor of 1.5 to 2. The sum of all other aberrations of second order or higher can likewise be small or remains small.

A deflection of particle beams substantially in different directions can be realized using magnetic fields pointing substantially in opposite directions; in this case, the magnetic field strengths in the two magnetic field regions may be substantially identical or may differ.

Manipulation parameters for the magnet arrangement are, for example, the positions (height or z-positions) of the entrance points or exit points into/from the various magnetic field regions and the associated entrance or exit angles or inclinations of the entrance regions and exit regions. By defining these manipulation parameters, it is possible (for a given magnetic field and a given kinetic energy of the charged particles) to set the respective arc length in a magnetic field region, along which the charged first individual particle beams move through the magnetic field regions.

The magnetic field regions themselves can be formed in a manner known per se. They are designed for example to form homogeneous magnetic fields, with the direction of the magnetic field being oriented orthogonal to the movement direction of the first individual particle beams. By way of example, the magnetic field regions can each be formed by two spaced apart slabs of magnetizable material, each with milled depressions into which current conductors or coils have been inserted. However, other embodiments are also possible.

The charged first individual particle beams can be, for example, electrons, positrons, muons or ions or other charged particles. The charged second individual particle beams can be mirror particles of the first charged individual particle beams; they can be secondary electrons or backscattered electrons. In principle, the particle-optical arrangement is therefore flexibly usable.

The terms primary particle-optical beam path and secondary particle-optical beam path are used as conventional in the art. However, attention is drawn here to the fact that the primary particle-optical beam path just like the secondary particle-optical beam path describe the paths of the plurality of first or second individual particle beams. For simplification, it may however naturally be—depending on context—that the terms primary particle-optical beam path or secondary particle-optical beam path only reference one individual particle beam moving along the particle-optical axis of the system, or the central beam. The central beam corresponds to the middle (i.e. central) individual particle beam of the bundle of individual particle beams. The direction of the particle-optical axis Z upon entrance into or exit from a magnetic field region is defined by the direction of the central beam, which can be identical to the centroid ray of all the individual particle beams of the beam bundle.

In accordance with an embodiment of the disclosure, the following relation applies to the exit inclination σ1 of the first magnetic field region: |σ1|≥0.5°, such as |σ1|≥1°, for example |σ1|≥3°, for example |σ1|≥5°. The exit inclination σ1 is therefore a “genuine” inclination and larger than this inclination would be merely owing to inaccuracies in adjustment. The sign or the direction of the inclination is generally dependent on the specific configuration of the magnet arrangement and also on the charge of the primary particle beams used.

In accordance with an embodiment of the disclosure, the following relation applies to the exit inclination σ1 of the first magnetic field region: 0°<|σ1|≤10°, such as 1°≤|σ1|≤9°, for example 3°≤|σ1|≤7°. Limiting the exit inclination σ1 to a maximum value may be expedient if the geometric ratios of the second particle-optical beam path, too, have to be taken into account. It is possible that a limited exit inclination σ1 contributes to limiting the incurring of aberrations of the secondary particle-optical beam path, too, upon traveling through the first magnetic field region. However, this is generally dependent on the specific configuration of a secondary path.

In accordance with an embodiment of the disclosure, the following relation applies to the entrance inclination φ1 of the first magnetic field region: |φ1|>0, for example |φ1|≥5° or |φ1|≥10°. In this case, the direction of the exit inclination σ1 can be opposite to the entrance inclination φ1. However, other forms of realization are also possible.

In accordance with an embodiment of the disclosure, the following relation applies to an entrance inclination φ2 of the second magnetic field region: |φ2|≤10°, such as |φ2|≤5°. Additionally or alternatively, the following applies to an exit inclination σ2 of the second magnetic field region: |σ2|≤10°, such as |σ2|≤5°. This limitation of the inclination angles can contribute to fewer aberrations occurring upon entering into the second magnetic field region and upon exiting from the second magnetic field region in the primary particle-optical beam path. The direction of the entrance inclination φ2 and the direction of the exit inclination σ2 can be different or opposite in terms of sign. However, it is also conceivable for the entrance inclination φ2 and the exit inclination σ2 to have the same sign.

According to an embodiment of the disclosure, the particle-optical arrangement further has a deflector arrangement arranged upstream of the second magnetic field region in the direction of the primary particle-optical beam path and configured to set the entrance direction of the primary particle-optical beam path into the second magnetic field region, and hence set the required entrance inclination φ2 with an accuracy of +/−0.1° or better, for example +/−0.05° or better, for example +/−0.025° or better, and configured to set the entrance location of the primary particle-optical beam path into the first magnetic field region with an accuracy of +/−0.3 mm or better, for example +/−0.1 mm or better, for example +/−0.05 mm or better. The deflector arrangement can comprise two adjustment deflectors which can be adjusted precisely and independently of one another such that it is possible to set, precisely and independently of one another, both the offset and the skew of the first individual particle beams upon entrance into the magnet arrangement. This can help prevent a possible recurrence of beam splitter aberrations, actually already corrected for via the design of the magnet arrangement, such as field inclination, field astigmatism, global astigmatism or other second-and third-order aberrations in the case of a skewed or offset beam input coupling. The adjustment deflectors can each be configured as electrostatic deflectors and/or magnetic deflectors, for example.

According to an embodiment of the disclosure, the direction of the magnetic fields in all of the magnetic field regions of the magnet arrangement is substantially orthogonal to the optical axis of the primary particle-optical beam path during the operation of the particle-optical arrangement and the magnetic fields are substantially homogeneous. The orbits in the magnet arrangement (circular orbits or helical orbits with an orbit radius r_{B}) described by the first individual particle beams can thus be adjustable in a better and more precise manner. For example, the following may apply to an orbit radius r_{B}: 0.1 m≤r_{B}≤10.0 m.

In accordance with an embodiment of the disclosure, the following relation applies to a sum SUM=(S1/R1)+(S2/R2): 0.60≤SUM≤0.80, such as 0.65≤SUM≤0.75. In this case, R1 denotes the radius and S1 denotes the arc length of the primary particle-optical beam path in the first magnetic field region. Correspondingly, R2 denotes the radius and S2 denotes the arc length of the primary particle-optical beam path in the second magnetic field region. The condition given above for the sum of the ratios of arc length to radius of the magnetic field regions can influence the magnitude of the focusing effect of the magnet arrangement in the first particle-optical beam path. This is because, on account of arising quadrupole fields, the charged first individual particle beams each experience focusing, albeit weak focusing, upon entrance into or exit from each magnetic field region. This focusing is not too strong. Limiting the focusing can help allow a simpler incorporation of the magnet arrangement or the particle-optical arrangement into a multi-beam particle microscope. Existing dimensions of an existing multi-beam particle microscope can be modified to a lesser extent, which facilitates the overall design.

In accordance with an embodiment of the disclosure, the following relation applies to a ratio V=(S2/R2)/(S1/R1) for the path of the primary particle-optical beam path in the first magnetic field region and in the second magnetic field region during operation of the particle-optical arrangement: 0.7≤V≤0.9, for example 0.75≤V≤0.85. In this case, once again R1 denotes the radius and S1 denotes the arc length of the primary particle-optical beam path in the first magnetic field region. Analogously, R2 denotes the radius and S2 denotes the arc length of the primary particle-optical beam path in the second magnetic field region. It holds true in general that a weaker and thus longer magnetic field region with a correspondingly longer arc length imposes smaller aberrations on the primary particle-optical beam path than a short magnetic field region which has a strong magnetic field and which causes the same deflection effect or the same deflection by the same angle. However, if only long and weak magnetic field regions are positioned in the magnet arrangement, then the total height of the magnet arrangement typically increases as a result. If there is a desire to keep the height of the magnet arrangement as constant as possible precisely with regard to the use of the magnet arrangement in a multi-beam particle microscope, then specific value ranges are desirable for the ratio V. A value of V<1 means here, in general, that it is desirable to control the first magnetic field region so as to be comparatively short, i.e. with a short arc length and also with a comparatively strong homogeneous magnetic field during operation. By contrast, the second magnetic field region can be controlled with a weaker magnetic field during operation and the second magnetic field region can at the same time be longer as well, thus resulting in a greater arc length S2.

According to an embodiment of the disclosure, a first drift region, which is substantially free from magnetic fields, is arranged in the primary particle-optical beam path between the first magnetic field region and the second magnetic field region. The provision of a drift region between the first magnetic field region and the second magnetic field region can be desirable in terms of the design of the particle-optical arrangement, especially in the case of a given entrance point into and given exit point from the particle-optical arrangement. This is because this case can lead to more mutually independent manipulation parameters for the magnet arrangement, offering more options for the correction of imaging aberrations. Moreover, a greater distance between the magnetic field regions can contribute to the reduction or avoidance of interaction effects between the magnetic field regions. Moreover, a spatial separation between the primary particle beams and the secondary particle beams can also be facilitated.

According to an embodiment of the disclosure, the drift region has a length LD to which the following applies: LD≥8 cm, such as LD≥10 cm. This length LD means that it is also readily possible for one or more magnetic field regions of (only) the second particle-optical beam path to be arranged at least partly in a gap between the first magnetic field region and the second magnetic field region or to be allowed to project somewhat into the gap.

According to an embodiment of the disclosure, an overall height of the magnet arrangement, as defined by a distance between the entrance point of the primary particle-optical beam path into the second magnetic field region and the exit point of the primary particle-optical beam path from the first magnetic field region, is less than or equal to 35 cm, such as less than or equal to 30 cm, for example less than or equal to 25 cm.

According to an embodiment of the disclosure, the magnet arrangement has no further magnetic field regions in the primary particle-optical beam path which are designed to deflect the primary particle-optical beam path by more than 2°, such as by more than 1°, for example by more than 0.5°. In other words, ideally exactly two magnetic field regions are provided in the primary particle-optical beam path according to this embodiment. Restricting the number of magnetic field regions in the primary particle-optical beam path means that the plurality of the first individual particle beams are not focused too strongly overall during the movement through the magnet arrangement. This is because, on account of arising quadrupole fields, the charged first individual particle beams can each experience focusing, albeit weak focusing, upon entrance into or exit from each magnetic field region. Limiting the magnetic field regions to a comparatively small number simultaneously also can limit this focusing, which is generally unwanted.

According to an embodiment of the disclosure, the first magnetic field region has two plates parallel to one another at a plate distance D1 from one another, between which a homogeneous magnetic field is generated during operation of the particle-optical arrangement. In this case, the entrance region of the first magnetic field region is linear and has a width BE1, wherein the following relation applies to a ratio VPE1=BE1/D1: VPE1≥2.5, such as VPE1≥3.0, for example VPE1≥3.5. Additionally or alternatively, the exit region of the first magnetic field region is linear and has a width BA1, wherein the following relation applies to a ratio VPA1=BA1/D1: VPA1≥2.5, such as VPA1≥3.0, for example VPA1≥3.5. The above ratios VPE1 and VPA1 contribute to the further reduction of aberrations. This applies for example to the field inclination and the field astigmatism. The linear entrance/exit region for the particle-optical beam path is situated between the two plates and is often also referred to as a trench. Accordingly, it could be desirable to make the width of the trenches as large as possible. From a structural standpoint, however, this might be possible or expedient only to a limited extent if arrangement of further magnetic field regions of the second particle-optical beam path is intended. These regions could collide with the magnetic field regions of the first particle-optical beam path. Another possibility for attaining the above ratio is to choose the distance between the two plates to be as small as possible, for example D1≤20 mm or D1≤15 mm.

According to an embodiment of the disclosure, the second magnetic field region has two plates parallel to one another at a plate distance D2 from one another, between which a homogeneous magnetic field is generated during operation of the particle-optical arrangement. In this case, the entrance region of the second magnetic field region is linear and has a width BE2, wherein the following relation applies to a ratio VPE2=BE2/D2: VPE2≥2.5, for example VPE2≥3.0 or VPE2≥3.5. Additionally or alternatively, the exit region of the second magnetic field region is linear and has a width BA2, wherein the following relation applies to a ratio VPA2=BA2/D2: VPA2≥2.5, such as VPA2≥3.0, for example VPA2≥3.5. The above ratios VPE1 and VPA1 can contribute to the further reduction of aberrations. This applies for example to the field inclination and the field astigmatism. The linear entrance/exit region for the particle-optical beam path is situated between the two plates and is often also referred to as a trench. Accordingly, it could be desirable to make the width of the trenches as large as possible. From a structural standpoint, however, this might be possible or expedient only to a limited extent if arrangement of further magnetic field regions of the second particle-optical beam path is intended. These regions could collide with the magnetic field regions of the first particle-optical beam path. Another possibility for attaining the above ratio is to choose the distance between the two plates to be as small as possible, for example D2≤20 mm or D2≤15 mm.

According to an embodiment of the disclosure, the magnet arrangement has a beam tube arrangement within which at least the first particle-optical beam path passes within the magnet arrangement. In this case, the following relation applies to a fill factor F of the beam tube arrangement during the operation of the particle-optical arrangement: F≤55%, such as F≤35%, for example F≤10%. In this case, the fill factor is given as the ratio of the maximum radius r of a beam bundle (the totality of the primary individual particle beams or the mFOV) to the internal radius Ri of the beam tube or the beam tube arrangement. In this case, the beam tube comprises a nonmagnetic material. For a given maximum radius r of the beam bundle, the internal radius Ri of the beam tube can be dimensioned accordingly. This can help minimize the contamination of the beam tube as a result of the interaction with the charged particle beams during operation, in order to try to avoid unwanted beam deflections on account of charged contamination spots on the inner side of the beam tube. The fill factor can be taken into account when choosing the plate distances D1, D2 of the magnetic field regions.

According to an embodiment of the disclosure, the following applies to a splitting angle γ through which the primary particle-optical beam path is deflected overall in the first magnetic field region during the operation of the particle-optical arrangement: γ≥14°, such as γ≥16°, for example γ≥18°. In this case, the splitting angle is a measure of the maximum possible separation of the primary particle-optical beam path from the secondary particle-optical beam path. The splitting angle γ is not too small, otherwise further magnetic field regions for the secondary particle-optical beam path cannot be integrated in the magnet arrangement of the particle-optical arrangement without problems. By way of example, further magnetic field regions which can be assigned exclusively to the secondary particle-optical beam path might collide with the magnetic field regions of the primary particle-optical beam path. By way of example, this may lead to crosstalk between different magnetic field regions.

According to an embodiment of the disclosure, the entrance inclination of the first magnetic field region is chosen so that an exit angle η of the secondary particle-optical beam path from this first magnetic field region is restricted to η≤35°, such as η≤25°, for example η≤15°. This can help avoid the collection of large aberrations when emerging from the first magnetic field region and additionally creates installation space for possible additional secondary path magnetic field regions in the gap between the first magnetic field region and the second magnetic field region. More details in this respect are given below.

According to an embodiment of the disclosure, the magnet arrangement has at least one further magnetic field region in the secondary particle-optical beam path following the passage of the first magnetic field region.

According to an embodiment of the disclosure, the magnet arrangement has at least two further magnetic field regions in the secondary particle-optical beam path following the passage of the first magnetic field region, the at least two further magnetic field regions being configured, in the case of a varying energy of secondary particles whose path forms the second particle-optical beam path, to precisely input couple, in terms of offset and angle, the particle-optical axis in the secondary beam path into a downstream projection optical unit. By way of example, the varying energy of the secondary particles may be the result of a modified setting of a landing energy.

According to an embodiment of the disclosure, the magnet arrangement has at least six further magnetic field regions and/or quadrupole fields in the secondary particle-optical beam path following the passage of the first magnetic field region, the at least six further magnetic field regions and/or quadrupole fields being configured, in the case of a varying energy of secondary particles whose path forms the second particle-optical beam path, to precisely input couple, in terms of offset and angle, the particle-optical axis in the secondary beam path into a downstream projection optical unit and additionally enable paraxial stigmatic, paraxial distortion-free and paraxial dispersion-free imaging.

According to an embodiment of the disclosure, at least one of the further magnetic field regions of the secondary particle-optical beam path is arranged in a gap between the first magnetic field region and the second magnetic field region of the primary particle-optical beam path.

According to an embodiment of the disclosure, the magnet arrangement further has a magnetic shielding wall arranged between at least one of the magnetic field regions of the primary particle-optical beam path and at least one of the magnetic field regions of the secondary particle-optical beam path. However, the wall can of course also be arranged substantially continuously between all magnetic field regions of the primary particle-optical beam path and all magnetic field regions of the secondary particle-optical beam path. By way of example, the magnetic shielding wall comprises a web of soft-magnetic material that minimizes crosstalk between primary and secondary path magnetic field regions.

According to an embodiment of the disclosure, the particle-optical arrangement is a multi-beam particle microscope and the particle-optical arrangement further has the following:
a multi-beam particle generator, which is configured to generate a first field of a plurality of charged first individual particle beams; a first particle-optical unit with a primary particle-optical beam path, configured to image the generated first individual particle beams onto an object plane such that the first individual particle beams impinge on an object at incidence locations, which form a second field; a detection unit with a plurality of detection regions which form a third field; a second particle-optical unit with a secondary particle-optical beam path, configured to image second individual particle beams, which emanate from the incidence locations in the second field, onto the third field of the detection regions of the detection system; a magnetic and/or electrostatic objective lens, through which both the first and the second individual particle beams pass;
and a controller, configured to control particle-optical components in the primary and/or in the secondary particle-optical beam path and/or components of the magnet arrangement, wherein the magnet arrangement is arranged in the first particle-optical beam path between the multi-beam particle generator and the objective lens and wherein the magnet arrangement is arranged in the second particle-optical beam path between the objective lens and the detection unit.

The charged first individual particle beams can be, for example, electrons, positrons, muons or ions or other charged particles. It is desirable for the number of first individual particle beams to be 3n (n−1)+1, where n is any natural number. The first individual particle beams can then be arranged in a hexagonal field. However, other arrangements of the first individual particle beams are also possible. The second individual particle beams can be backscattered electrons or else secondary electrons. In this case, for analysis purposes it is possible for the low-energy secondary electrons to be used for image generation. However, it is also possible for mirror ions/mirror electrons to be used as second individual particle beams, which is to say first individual particle beams undergoing reversal directly upstream of the object or at the object.

Naturally, the magnet arrangement of the multi-beam particle microscope can still be extended or improved for the secondary particle-optical beam path, as has already been described hereinabove. According to an embodiment, the magnet arrangement has at least one further magnetic field region in the secondary particle-optical beam path. By way of example, it is possible to arrange one or two or three further magnetic field regions in the secondary particle-optical beam path, as has already been described in EP 1 668 662 B1. As a result, imaging aberrations as a result of the magnet arrangement or the beam splitter can also be corrected in the secondary particle-optical beam path.

According to an embodiment of the disclosure, the particle-optical axis A of the objective lens corresponds to the direction of the particle-optical axis Z of the primary particle-optical beam path upon emerging from the first magnetic field region. In this case, the exit region of the first particle-optical beam path from the first magnetic field region is not orthogonal to the particle-optical axis A of the objective lens. In this embodiment of the disclosure, the exit inclination σ1 of the first magnetic field region, which deviates from 0°, thus has a genuine visible consequence. In illustrative terms, therefore, the exit region of the first particle-optical beam path from the first magnetic field region is skewed relative to the normal to the particle-optical axis A of the objective lens. The fact that particle-optical imagings with significantly reduced aberrations can be achieved in the case of this geometric arrangement is surprising and has been found in the course of simulations, although very clearly and significantly therein. The objective lens can comprise an objective lens system comprising magnetic and/or electrostatic lenses.

According to an embodiment of the disclosure, the following relation applies to a distance OLBS between the objective lens and the exit region of the first magnetic field region: OLBS≤75 mm, such as OLBS≤70 mm. The distance between the magnet arrangement and the objective lens is therefore comparatively small. This can contribute to reducing the overall structural height of the multi-beam particle microscope. This is relevant particularly in laboratory environments, in which the ceiling height or room height is typically limited.

According to an embodiment of the disclosure, the imaging of the plurality of the first individual particle beams into the object plane is substantially distortion-free overall, and/or
the imaging of the first individual particle beams into the object plane is substantially dispersion-free; and/or the incidence locations of the first individual particle beams in the object plane are astigmatic and round. Additionally or alternatively, it is also possible to correct other aberrations within the scope of the particle-optical imaging. Depending on the design, the magnet arrangement according to the disclosure offers appropriate manipulation parameters for correction purposes. The correction may also comprise a correction of a skew of the sample and/or a correction of a focal tilt as a result of a maladjustment of an illumination system/condenser lens system.

According to an embodiment of the disclosure, the imaging of the first individual particle beams into the object plane has substantially no field inclination.

According to an embodiment of the disclosure, the imaging of the first individual particle beams into the object plane is substantially field astigmatism-free.

According to an embodiment of the disclosure, the sum of all other aberrations of second and third order in the object plane is no more than only 1 nm, for example no more than only 0.5 nm or no more than only 0.25 nm. In this case, the stated values are scaled using the used numerical aperture NA and the image field size in the object plane and are determined for a landing energy of 1.5 keV.

The above-described embodiments can be combined with one another in full or in part, provided that no technical contradictions arise as a result.

### BRIEF DESCRIPTION OF THE DRAWINGS

The disclosure will be understood even better with reference to the accompanying figures. In the figures:

FIG. 1: schematically shows a multi-beam particle microscope;

FIG. 2: schematically shows a multi-beam particle microscope with a beam splitter or magnet arrangement according to the prior art;

FIG. 3: schematically shows a magnet arrangement according to the prior art and the occurrence of a field inclination;

FIG. 4: schematically shows manipulation parameters in the case of a magnet arrangement with two magnetic field regions in the primary path according to the prior art;

FIG. 5: schematically shows manipulation parameters in the case of a magnet arrangement with two magnetic field regions in the primary path;

FIG. 6: schematically shows inclinations of an entrance region and an exit region of the first magnetic field region in the primary path;

FIG. 7: schematically shows inclinations of an entrance region and an exit region of the second magnetic field region in the primary path;

FIG. 8: schematically shows a deflector arrangement upstream of the second magnetic field region in the primary path; and

FIGS. 9A-9B: schematically show geometric ratios of the first magnetic field region;

FIGS. 10A-10B: schematically show geometric ratios of the second magnetic field region;

FIG. 11: schematically illustrates a fill factor of the beam tube arrangement;

FIG. 12: schematically shows a shielding wall between magnetic field regions of the primary path and the secondary path; and

FIG. 13: schematically shows an arrangement or alignment of the first magnetic field region in the particle-optical beam path in relation to the secondary path.

### DETAILED DESCRIPTION

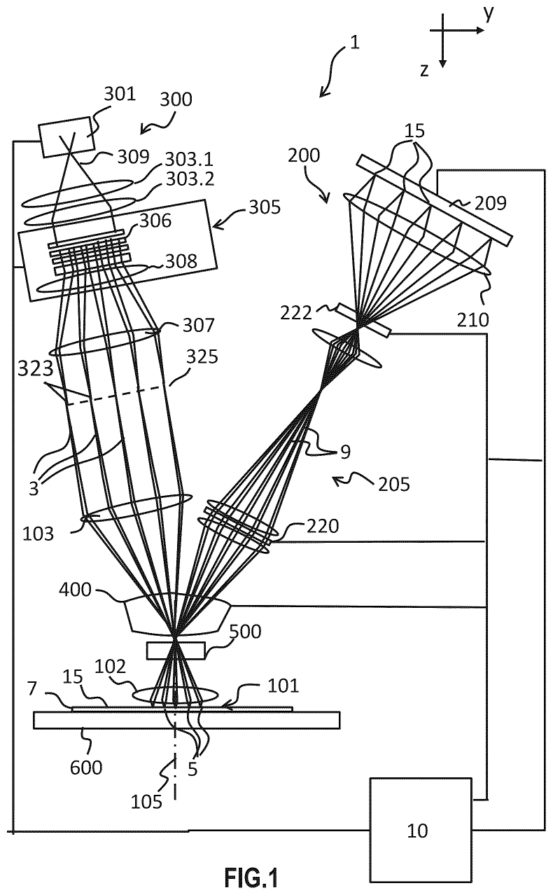

FIG. 1 schematically shows a multi-beam particle microscope 1. The multi-beam particle microscope 1 comprises a beam generating apparatus 300 with a particle source 301, for instance an electron source. A divergent particle beam 309 is collimated by a sequence of condenser lenses 303.1 and 303.2 and incident on a multi-aperture arrangement 305. The multi-aperture arrangement 305 comprises a plurality of multi-aperture plates 306 and a field lens 308. A multiplicity of individual particle beams 3 or individual electron beams 3 are generated by the multi-aperture arrangement. Midpoints of apertures in the multi-aperture plate arrangement are arranged in a field which is imaged on a further field formed by beam spots 5 in the object plane 101. The pitch between the midpoints of apertures of a multi-aperture plate 306 can be for instance 5 μm, 100 μm and 200 μm. The diameters D of the apertures are smaller than the pitch of the midpoints of the apertures; examples of the diameters are 0.2 times, 0.4 times and 0.8 times the pitch between the midpoints of the apertures.

The multi-aperture arrangement 305 and the field lens 307 are configured to generate a multiplicity of focal points 323 of primary beams 3 in a grid arrangement on a surface 325. The surface 325 need not be a plane surface but rather can be a spherically curved surface in order to account for a field curvature of the subsequent particle-optical system.

The multi-beam particle microscope 1 further comprises a system of electromagnetic lenses 103 and an objective lens 102, which image the beam foci 323 from the intermediate image surface 325 into the object plane 101 with reduced size. In between, the first individual particle beams 3 pass through the beam splitter 400 and a collective beam deflection system 500, by which the plurality of the first individual particle beams 3 are deflected during operation and the image field is scanned. The first individual particle beams 3 incident in the object plane 101 for example form a substantially regular field, wherein the pitch between adjacent incidence locations 5 can be 1 μm, 10 μm or 40 μm, for example. For instance, the field formed by the incidence locations 5 can have a rectangular or hexagonal symmetry.

The object 7 to be examined can be of any desired type, for instance a semiconductor wafer or a biological sample, and can comprise an arrangement of miniaturized elements or the like. The surface 15 of the object 7 is arranged in the object plane 101 of the objective lens 102. The objective lens 102 can comprise one or more electron-optical lenses. For instance, this can be a magnetic objective lens and/or an electrostatic objective lens.

The primary particles 3 incident on the object 7 generate interaction products, for example secondary electrons, backscattered electrons or primary particles which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 downstream of the objective lens 102 and are supplied to a projection system 200. The projection system 200 comprises an imaging system 205 with first and second lenses 210 and 220, a contrast stop 222 and a multi-particle detector 209. Incidence locations of the second individual particle beams 9 on detection regions of the multi-particle detector 209 are located in a third field with a regular pitch from one another. Exemplary values are 10 μm, 100 μm and 200 μm.

The multi-beam particle microscope 1 furthermore comprises a computer system or control unit 10, which in turn can be embodied integrally or in multipartite fashion and which is designed both to control the individual particle-optical components of the multi-beam particle microscope 1 and to evaluate and analyze the signals obtained by the multi-detector 209 or detection unit 209.

Further information relating to such multi-beam particle beam systems or multi-beam particle microscopes 1 and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is fully incorporated by reference in the present application.

The beam splitter 400 or magnet arrangement 400 is depicted only schematically and without further details in FIG. 1. In principle, it is possible for the magnet arrangement 400 to be the magnet arrangement 400 which is contained in the particle-optical arrangement according to the disclosure. However, the beam splitter 400 known from the prior art or from EP 1 668 662 B1 is also compatible with the multi-beam particle microscope 1 according to FIG. 1.

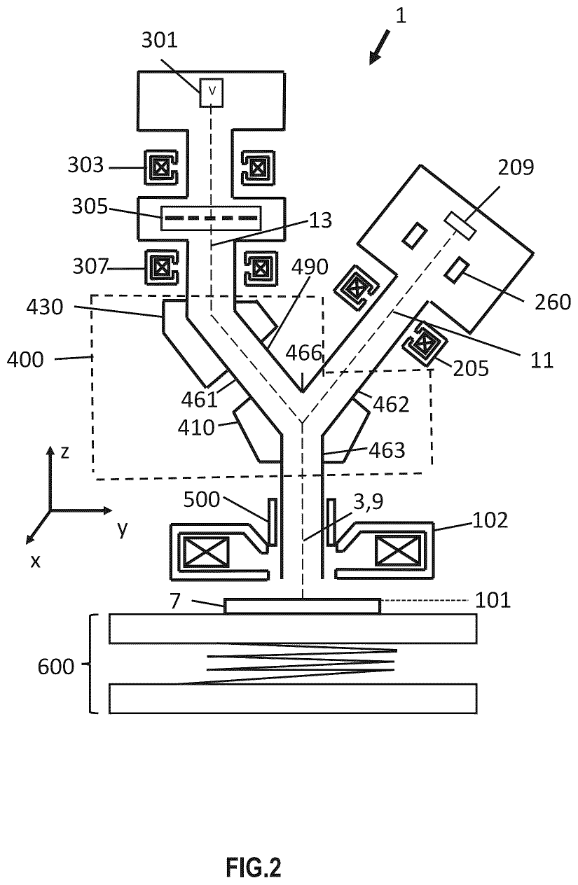

FIG. 2 schematically shows a sectional illustration of a multi-beam particle microscope 1 with a beam splitter 400 or magnet arrangement 400 according to the prior art. For example, aspects of the known beam splitter 400 are explained here. In the multi-beam particle microscope 1 depicted in FIG. 2, a particle beam which is emitted by a particle source 301 passes through a magneto-optic condenser lens system 303 and subsequently impinges on the multi-aperture arrangement 305. The latter serves as a multi-beam particle generator, and individual particle beams 3 emanating from the multi-aperture arrangement 305 thereupon pass through a magneto-optic field lens system 307 and subsequently enter the magneto-optic beam splitter 400 or magnet arrangement 400. The depicted beam splitter 400 comprises a beam tube arrangement 490, which has a Y-shaped embodiment and comprises three limbs 461, 462 and 463 in the example shown. Here, in addition to two flat, interconnected structures for holding the magnetic sectors or magnetic field regions 410, 430, the beam splitter 400 includes the two magnetic sectors or magnetic field regions 410 and 430 which are contained in, or secured to, the structures. After passing through the beam splitter 400, the first particle beams 3 pass through a scan deflector 500 and, thereupon, the particle-optical objective lens 102, before the primary particle beams 3 are incident on the surface 15 of an object 7, in this case a semiconductor wafer with HV structures. In this case, HV structures denote the predominantly horizontal or vertical profile of semiconductor structures. In this case, the semiconductor wafer 7 is positioned by a displacement stage 600 below the objective lens 102. As a result of the incidence of the first individual particle beams 3, secondary particles or second individual particle beams 9 are released from the object 7. After emerging from the object 7, the second individual particle beams 9 initially pass through the particle-optical objective lens 102 and subsequently pass through the scan deflector 500 and then the beam splitter 400. From the beam splitter 400, the second individual particle beams 9 emerge from the limb 462, pass through a projection lens system 205 (illustrated in much-simplified fashion), pass through an electrostatic element 260, the so-called anti-scan, and then impinge on a particle-optical detection unit 209. The computer system 10 or the control unit 10, serving to control particle-optical components and other constituent parts of the multi-beam particle microscope 1 according to FIG. 2, is not depicted in FIG. 2 in order to keep things simple.

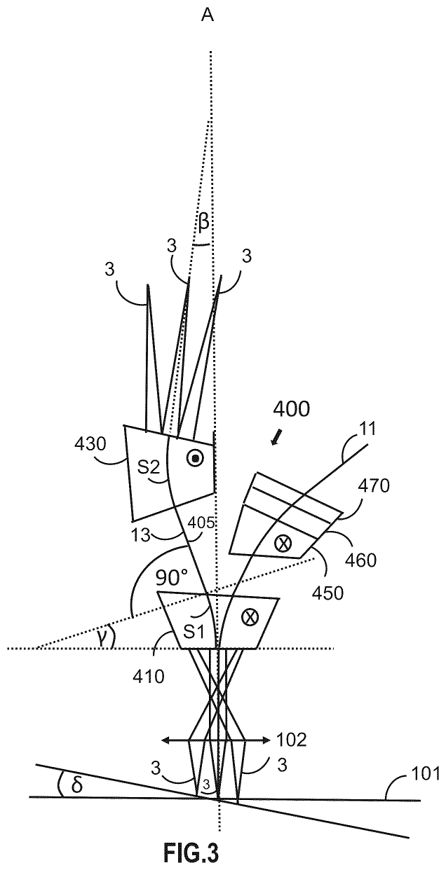

FIG. 3 schematically shows a magnet arrangement according to the prior art and the occurrence of a field inclination. In the example shown, the magnet arrangement 400 comprises a first magnetic field region 410 and a second magnetic field region 430, the magnetic fields of which are oriented in the opposite sense to one another, and a primary particle-optical beam path 13 travels through both of these magnetic field regions. Moreover, three further magnetic field regions 450, 460 and 470 are provided in the example shown. The secondary particle-optical beam path 11 extends through the first magnetic field region 410 and through these additional magnetic field regions 450, 460 and 470. The magnetic field in the magnetic field region 450 is oriented in the same direction as the magnetic field in the magnetic field region 410, with the result that the curvature of the second particle-optical beam path 11 is without a change of curvature in these magnetic field regions 410, 450.

In the case of the beam splitter shown in FIG. 3, there is a skew angle β between the optical axis of the first particle-optical beam path 13 and the axis A, which corresponds to the particle-optical axis of the objective lens 102 or the continuation thereof. A right angle is set between a lower edge of the first magnetic field region 410 and the axis A, which according to the prior art is regarded as desirable for the properties of imaging into the object plane 101 overall.

The angle γ is the so-called splitting angle, which provides a measure of the separation of the primary particle-optical beam path 13 from the second particle-optical beam path 11 within the magnetic field region 410. This angle is not too small, otherwise there might not be sufficient installation space available for the arrangement of magnetic field regions 450, 460 and 470 (and possibly further elements of the magnet arrangement 400) in the secondary particle-optical beam path 11.

Imaging aberrations of the first particle-optical beam path 13 may be largely corrected and the imaging can be substantially stigmatic to a first order and substantially distortion-free to a first order. However, there are ever greater demands on the resolution within the scope of ever more accurate measurement tasks for multi-beam particle microscopes 1 and it turned out that a field inclination [symbol] of the beam splitter 400 depicted in FIG. 3 often makes up the majority of the remaining residual aberration. In FIG. 3, this field inclination [symbol] has not been plotted true to scale. First individual particle beams 3 impinge on the object or the object plane 101 at slightly different heights, wherein the location of the minimum particle beam diameter is considered to be the focus in this case. The individual particle beam 3 located exactly on the particle-optical axis A has a focal position exactly on the object plane 101, the first individual particle beam 3 arranged to the left thereof has a focal position arranged just in front of the object plane 101 and the first individual particle beam 3 arranged to the right of the particle-optical axis A has a focal position slightly below the object plane 101. The occurrence of the field inclination [symbol] is explained substantially by slightly different path lengths traversed by the plurality of the first individual particle beams 3 within the magnet arrangement 400. Hitherto in the prior art it has not been possible to compensate for the field inclination [symbol] in the design of the magnet arrangement 400 with only two magnetic field regions 410, 430 in the primary path.

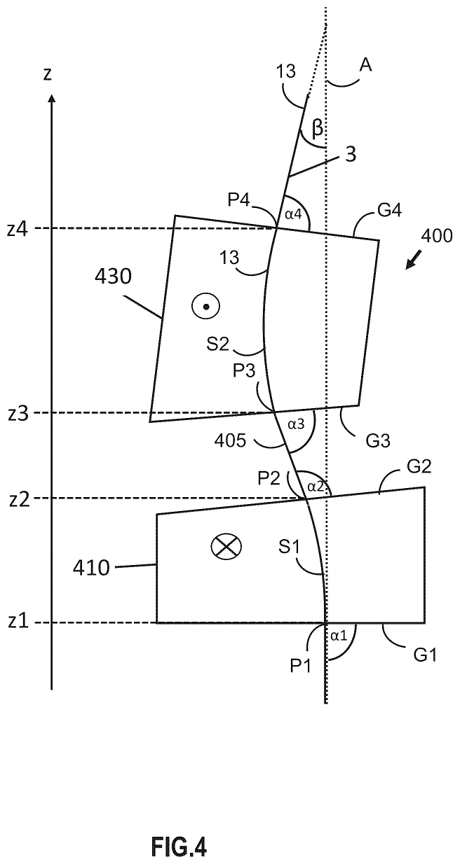

FIG. 4 schematically shows manipulation parameters in the case of a magnet arrangement 400 according to the prior art with two magnetic field regions 410 and 430 in the primary path 13; the secondary path is not depicted in FIG. 4. In order to obtain a perpendicular emergence of the primary particle-optical beam path 13 from the first magnetic field region 410 and good imaging properties at the objective lens (not illustrated), the exit point P1 and the inclination of the exit region G1 are fixed in a design of the magnetic field arrangement 400, the angle α1 is 90° and the position in the direction of the Z-axis is defined as z1. Thus, the remaining entrance regions and exit regions into/from the magnetic field regions 410, 430 are available for the adaptation of particle-optical properties. By way of example, the points P2, P3 and P4 can be described by their z-positions z2, z3, z4 and by the angles α2, α3 and α4; however, other coordinates may naturally also be chosen to this end. In principle, the respective arc lengths S2 and S1 in the magnetic field regions 430 and 410 are adapted by an appropriate choice or definition of the points P2, P3 and P4. A drift path 405 is arranged between the points P2 and P3, the length of the drift path arising from the definition of the points P2 and P3.

If the point P1 is kept fixed, and the inclination of the exit region G1 and the magnetic field strength in the magnetic field regions 410 and 430 are defined, then the system shown in FIG. 4 has a maximum of six independent manipulation parameters: the z-positions z2, z3 and z4 and the angles α2, α3 and α4. These six manipulation parameters can be used to optimize the imaging properties of the magnet arrangement 400 and reduce aberrations. However, a complete compensation of path differences and hence a substantial elimination of a field inclination in addition to already corrected aberrations is only possible, if at all, for certain incoming radiation conditions in the case of the arrangement shown in FIG. 4.

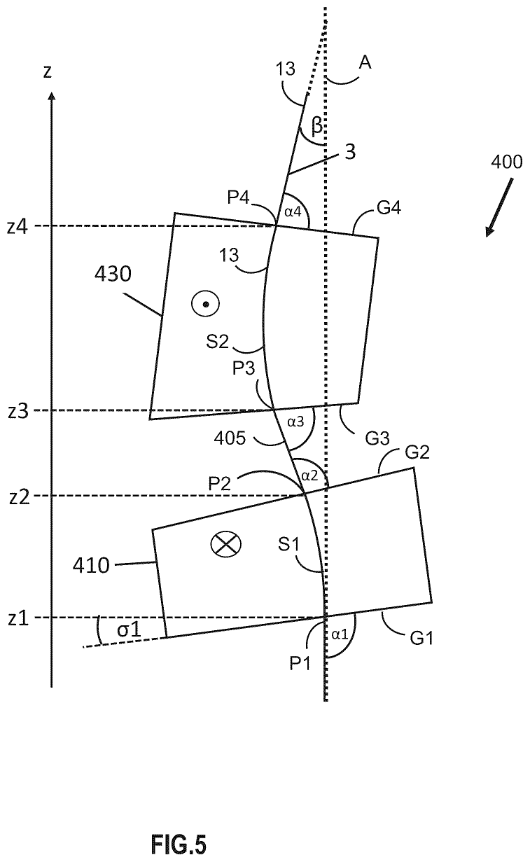

FIG. 5 schematically shows a magnet arrangement 400 with once again two magnetic field regions 410, 430 in the primary path 13. The geometric arrangement of the magnet arrangement 400 according to FIG. 5 differs from the illustration shown in FIG. 4 in an aspect: The angle α1 between the exit region G1 and the particle-optical axis A is not 90°. Instead, the exit region G1 is inclined or skewed relative to the normal to the direction of the particle-optical beam path 13 at the exit point P1. This exit inclination σ1 of the first magnetic field region 410 relative to the normal to the particle-optical axis Z of the primary particle-optical beam path 13 is additionally depicted in FIG. 5. Altering the exit inclination σ1 leads to significantly reduced aberrations in the design of the magnet arrangement. For example, a field inclination δ and also a field astigmatism can be substantially eliminated as a result. Other second-order and higher-order aberrations can also be correspondingly minimized or vary in terms of order of magnitude in the range that is also known from the magnet arrangement 400 according to FIG. 4.

A possible variation of the exit inclination σ1 provides a further degree of freedom for the design of the magnet arrangement given a fixed position of the exit point P1 and, surprisingly, it is precisely this non-intuitive manipulation parameter α1 or σ1 that is a key to the significant further reduction of aberrations. The magnet arrangement 400 or its geometric representation in FIG. 5 is of course not true to scale. According to one example, the following relation applies to the exit inclination σ1 of the first magnetic field region 410:|σ1|≥0.5°, such as |σ1|≥1°, for example |σ1|≥3°, for example |σ1|≥5°. The exit inclination σ1 of the first magnetic field region 410 thus in part deviates significantly from 0°; in any case the deviation is greater than an adjustment inaccuracy which may constitute for example a deviation of +/−0.1° or +/−0.05° or better. According to a further example, the exit inclination σ1 of the first magnetic field region can satisfy the following relation: 0°<|σ1|≤10°, for example 1°≤|σ1|≤9° or 3°≤|σ1|≤7°.

In FIG. 5, a drift path 405 is arranged between the second magnetic field region 430 and the first magnetic field region 410, on which drift path the charged first individual particle beams 3 move rectilinearly or the primary path 13 extends rectilinearly. The following can apply to the length LD of this drift path 405, for example: LD≥8 cm, such as LD≥10 cm.

It has moreover been found to be desirable for an overall length of the magnet arrangement 400, as defined by a distance between the entrance point P4 of the primary particle-optical beam path 13 into the second magnetic field region 430 and the exit point P1 of the primary particle-optical beam path 13 from the first magnetic field region 410, to be less than or equal to 35 cm, such as less than or equal to 30 cm, for example less than or equal to 25 cm. This facilitates the incorporation of the magnet arrangement into particle-optical systems or into multi-beam particle microscopes, which are often set up in laboratory rooms with restricted ceiling height.

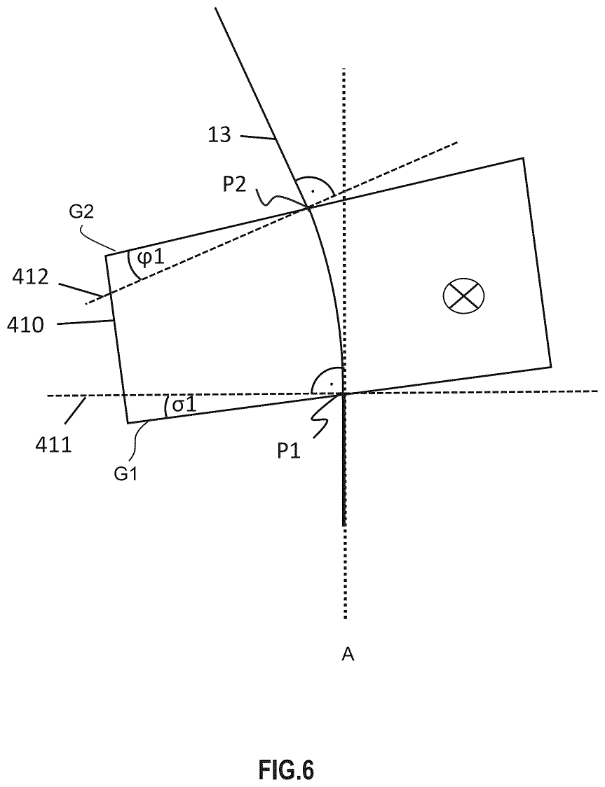

FIG. 6 schematically shows inclinations of an entrance region G2 and an exit region G1 of the first magnetic field region 410 in the primary path. FIG. 6 illustrates that not only does the exit region G1 have an exit inclination σ1 but also the entrance region G2 is inclined relative to a normal to the particle-optical beam path at the entrance location P2 into the first magnetic field region 410, specifically by the angle φ1. By way of example, the following relation can apply to an entrance inclination φ1 of the first magnetic field region 410:|φ1|>0, such as |φ1|≥5°, for example |φ1|≥10°. In the example shown, the inclinations φ1 and σ1 have opposite directions. However, theoretically it is also possible for the inclination directions to have the same sign or the same sense of rotation. In FIG. 6, furthermore, the particle-optical axis A is depicted as an imaginary lengthening of the particle-optical axis of the objective lens 102 of a multi-beam particle microscope 1. It is pointed out, however, that the definition of the inclinations σ1 and φ1 is independent of this particle-optical axis A, rather that the inclinations σ1 and φ1 are defined solely with reference to the direction of the particle-optical beam path Z and to the entrance and exit regions G2, G1. The normals 411, 412 to the particle-optical axis Z are likewise depicted as dashed subsidiary lines in FIG. 6.

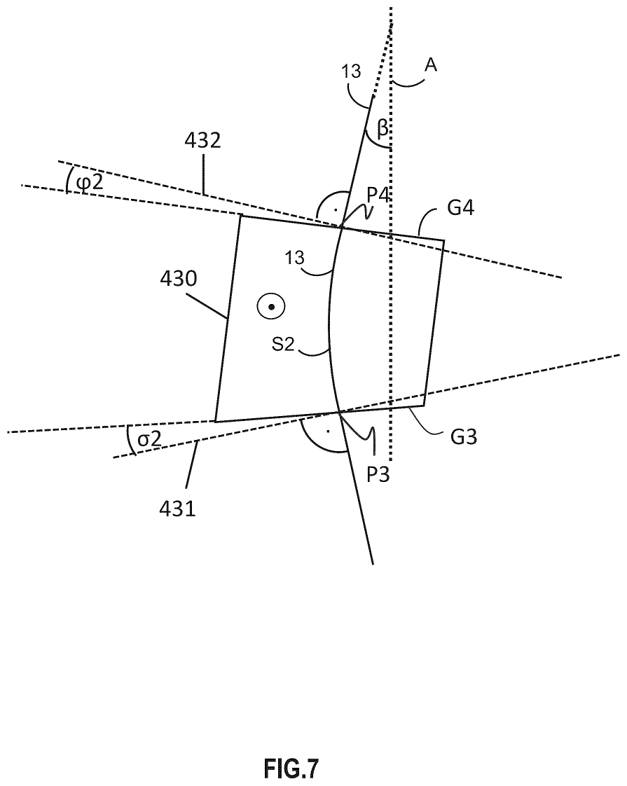

FIG. 7 schematically shows inclinations of an entrance region G4 and an exit region G3 of the second magnetic field region 430 in the primary path 13. The entrance inclination φ2 of the second magnetic field region 430 is in turn defined as the angle by which the alignment of the entrance region G4 deviates from the normal 432 to the particle-optical axis Z of the primary particle-optical beam path 13 at the entrance location P4. Totally analogously, the exit inclination σ2 is defined as the angle by which the alignment of the exit region B3 deviates from the normal 431 to the particle-optical axis Z of the primary particle-optical beam path 13 at the point P3. According to one exemplary embodiment, the following relation applies to the entrance inclination φ2 of the second magnetic field region 430:|φ2|≤10°, such as |φ2|≤5°. Additionally or alternatively, the following relation can apply to an exit inclination σ2 of the second magnetic field region 430:|σ2|≤10°, such as |σ2|≤5°. The smaller the inclinations |φ2|and |σ2|the fewer the aberrations incurred by the charged particles or individual particle beams 3 upon entering into and exiting from the magnetic field region 430.

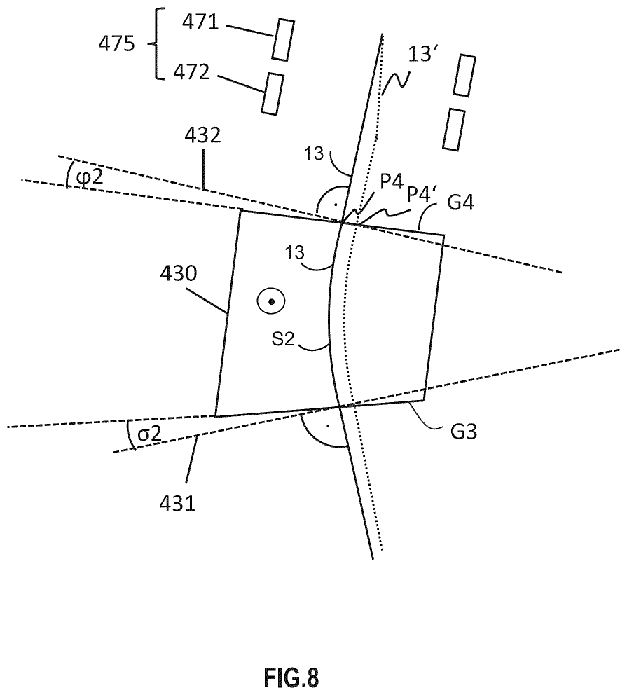

It has been found that the entrance inclination φ2 is set very accurately in order to significantly reduce second-order imaging aberrations such as field inclination and field astigmatism. Deviations from the previously determined angle φ2 have relatively great effects on otherwise recurring and actually eliminated aberrations. Therefore, the particle-optical arrangement according to a further exemplary embodiment has a deflector arrangement 475 arranged upstream of the second magnetic field region 430 in the direction of the primary particle-optical beam path 13. In the example shown, the deflector arrangement 475 is configured as a double deflector comprising the deflectors 471 and 472. These can be electrostatic and/or magnetic deflectors. The deflector arrangement 475 is configured to set the entrance direction of the primary particle-optical beam path 13 into the second magnetic field region 430 and thus the entrance inclination φ2 with an accuracy of +/−0.1° or better, such as +/−0.05° or better, for example +/−0.025° or better. Furthermore, the deflector arrangement 475 is configured to set the entrance location P4 or P4′ of the primary particle-optical beam path 13, 13′ into the second magnetic field region 430 with an accuracy of +/−0.3 mm or better, for example of +/−0.1 mm or better or even +/−0.05 mm or better. The different setting options are represented by the dashed particle-optical beam path 13′ merely schematically and in a greatly exaggerated manner in FIG. 8 and serve merely for illustration.

Generally, for example, two adjustment deflectors 471, 472 can be adjusted precisely and independently of one another via the deflector arrangement, such that it is possible to set, precisely and independently of one another, both the offset and the skew of the first individual particle beams 3 upon entrance into the magnet arrangement 400. This prevents a possible recurrence of beam splitter aberrations, actually already corrected for by the design of the magnet arrangement 400, such as field inclination, field astigmatism, global astigmatism or other second-or third-order aberrations in the case of a skewed or offset beam input coupling.

In addition to the above-described manipulation parameters of the entrance locations P1 to P4 and the entrance and exit inclinations σ1, φ1, σ2 and φ2, there are in principle further manipulation parameters for the design of the magnet arrangement 400. These may be dependent on or independent of the manipulation parameters mentioned above. According to one exemplary embodiment, the directions of the magnetic fields in the first and second magnetic field regions 410, 430 of the magnet arrangement 400 are substantially orthogonal to the particle-optical axis Z of the primary particle-optical beam path 13 during the operation of the particle-optical arrangement and the magnetic fields are substantially homogeneous. In the exemplary embodiments illustrated in FIGS. 3 to 8, the magnetic fields in the magnetic field regions 410 and 430 are oriented oppositely to one another. The magnetic field strength can then likewise be varied (as a dependent manipulation parameter). In this case, the magnetic field strength in the first magnetic field region 410 can have a different absolute value than the magnetic field strength in the second magnetic field region 430. The magnetic field strength in the first magnetic field region 410 can be greater than that in the second magnetic field region 430. An associated arc length S1 in the first magnetic field region 410 can be shorter than the arc length S2 in the second magnetic field region 430. In accordance with one exemplary embodiment, it can then hold true that the following relation applies to a ratio V=(S2/R2)/(S1/R1) for the path of the primary particle-optical beam path 13 in the first magnetic field region 410 and in the second magnetic field region 430 during operation of the particle-optical arrangement: 0.7≤V≤0.9, such as 0.75≤V≤0.85. In this case, R1 denotes the radius and S1 the arc length of the primary particle-optical beam path 13 in the first magnetic field region 410 and, correspondingly, R2 denotes the radius and S2 the arc length of the primary particle-optical beam path 13 in the second magnetic field region 430. A ratio V that varies in the abovementioned range contributes to reducing aberrations even further.

Furthermore, the following relation can apply to a sum SUM=(S1/R1)+(S2/R2): 0.60≤SUM≤0.80, such as 0.65≤SUM≤0.75. This can contribute to leaving the focusing effect of the magnet arrangement 400 in an acceptable range that is as small as possible.

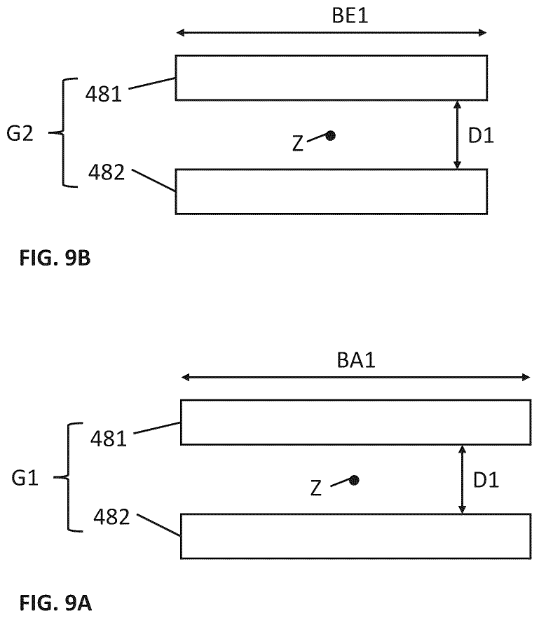

FIGS. 9A-9B schematically show further geometric ratios of the first magnetic field region 410, which as independent manipulation parameters can further contribute to reducing aberrations: The illustration in FIG. 9A at the bottom shows the entrance region G1 of the first magnetic field region 410, the particle-optical axis Z pointing into the plane of the drawing in the example shown. The first magnetic field region 410 has two plates 481, 482 parallel to one another, which are at a distance D1 from one another in the example shown. The plates 481, 482 spaced apart from one another can comprise (or consist of) magnetizable material, and each of the plates 481, 482 can have milled depressions into which current conductors or coils have been inserted. However, other embodiments for the two plates 481, 482 parallel to one another are also possible. The exit region G1 of the first magnetic field region 410 is linear and has a width BA1. As a result, in principle, the entire exit region G1 or trench is linear and the width BA1 can be defined in the first place. It has now been found that a ratio of trench width BA1 to plate distance D1 can be desirable if the following relation is satisfied for the ratio VPA1=WA1/D1: VPA1≥2.5, such as VPA1≥3.0, for example VPA1≥3.5. Specifically, aberrations can then be reduced even further. The same analogously also applies to the ratio VPE1=BE1/D1, where BE1 denotes the width of the entrance region of the first magnetic field region 410, which is illustrated in FIG. 9B. Here, too, it can be desirable to have reducing aberrations if the following relation applies: VPE1≥2.5, such as VPE1≥3.0, for example VPE1≥3.5.

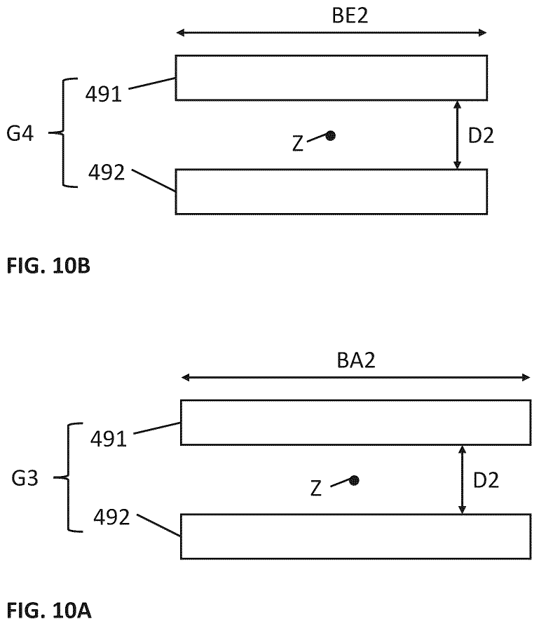

Totally analogously, these desirable geometric conditions also apply for the realization of the second magnetic field region 430. This is illustrated schematically in FIGS. 10A-10B. In the exemplary embodiment shown, the plates 491 and 492 of the second magnetic field region 430 are spaced apart by the distance D2. The width of the entrance region is denoted by BE2 and the width of the exit region is denoted by BA2. It is now once again desirable for the following relation to apply to the ratio VPE2=BE2/D2: VPE2≥2.5, such as VPE2≥3.0, for example VPE2≥3.5. Correspondingly, the following relation can apply to a ratio VPA2=BA2/D2: VPA2≥2.5, such as VPA2≥3.0, for example VPA2≥3.5.

In the exemplary embodiments illustrated in FIGS. 9A-9B and 10A-10B, it may be the case that the width of the respective entrance region BE1, BE2 is identical to the width of the respective exit region BA1, BA2. However, these widths can also be different. Furthermore, it is possible for the plate distance D1 in the first magnetic field region 410 to be identical to the plate distance D2 of the second magnetic field region 430. However, it is also possible for the plate distances D1 and D2 to differ from one another. A plate distance D1 or D2 can be for example ≤25 mm, ≤20 mm or ≤15 mm. However, it is desirable here to take account of how many individual particle beams 3 overall travel through the magnet arrangement 400 during operation of the particle-optical arrangement. In this case, the charged individual particle beams 3 do not come too close to the plates 491, 492, 481, 482, in order to avoid imaging aberrations and/or contaminations.

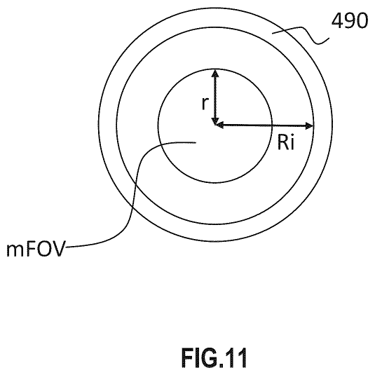

FIG. 11 illustrates considerations regarding the so-called fill factor of a beam tube 491. According to one exemplary embodiment, the magnet arrangement 400 has a beam tube arrangement 490 within which the primary particle-optical beam path 13 passes within the magnet arrangement 400. FIG. 11 illustrates a beam bundle mFOV passing through the beam tube 490 and having an external radius r. By contrast, the beam tube 490 has a maximum internal radius Ri. The fill factor is defined, then, as the ratio of the maximum radius r of the beam bundle mFOV to the internal diameter Ri of the beam tube 490. According to one exemplary embodiment, the following relation applies to this fill factor F: F≤55%, such as F≤35%, for example F≤10%. If the fill factor F is too high, then unwanted contaminations of the beam tube 490 may occur or, during operation of the particle-optical arrangement, interactions between firstly contaminations of the beam tube 490 and secondly the charged particle beams 3, 9 may occur during operation. This results in unwanted beam deflections by charged contamination spots on the inner side of the beam tube 490. In this respect, a plate distance D1, D2 cannot be minimized arbitrarily, rather care is taken to ensure that a beam tube 490 in the particle-optical beam path 13 in the interior of the magnet arrangement 400 also satisfies these desired fill factor F.

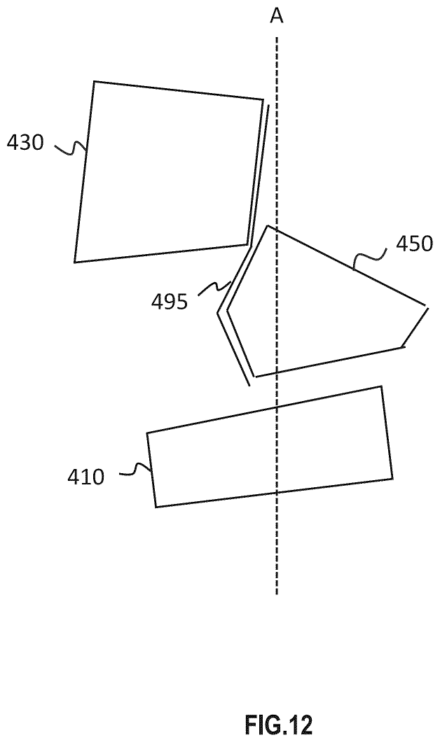

FIG. 12 schematically shows a shielding wall 495 between magnetic field regions of the primary path and the secondary path. According to this exemplary embodiment, the magnet arrangement 400 has a magnetic shielding wall 495 arranged between at least one of the magnetic field regions 410, 430 of the primary particle-optical beam path 13 and at least one of the magnetic field regions of the secondary particle-optical beam path 11. Naturally, it may however also be arranged substantially continuously between all magnetic field regions 410, 430 of the primary particle-optical beam path 13 and all magnetic field regions of the secondary particle-optical beam path 11. By way of example, the magnetic shielding wall 495 comprises a web of soft-magnetic material, which minimizes crosstalk between primary path and secondary path magnetic field regions. In the example shown in FIG. 12, at least one magnetic field region 450 of the secondary path 11 projects in between the first magnetic field region 410 and the second magnetic field region 420 to such an extent that it intersects the imaginary lengthening of the particle-optical axis A of an objective lens 102 when the magnet arrangement 400 is integrated as a beam splitter 400 into a multi-beam particle microscope 1. However, this could also be different.

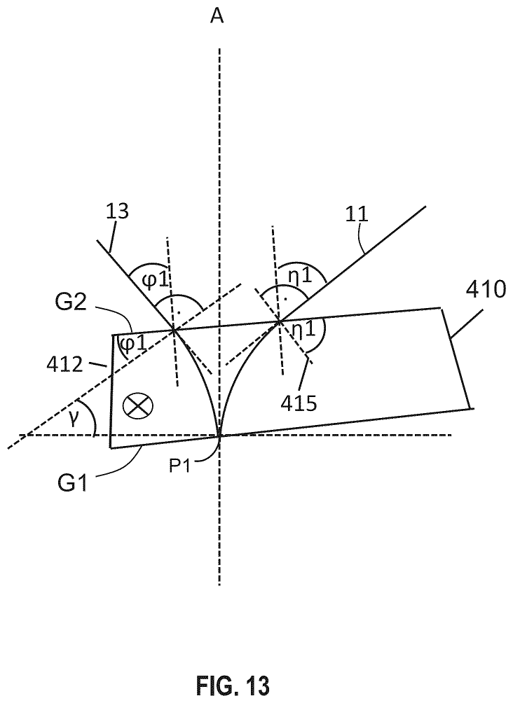

FIG. 13 schematically illustrates an arrangement or alignment of the first magnetic field region 410 in the particle-optical beam path. The exit inclination of the exit region or trench G1 from the first magnetic field region 410 differs from 0°, as in the previous exemplary embodiments. Consequently, there is no right angle between the exit region or trench G1 and the particle-optical axis A. The exit direction from the first magnetic field region 410 nevertheless corresponds to the direction of the particle-optical axis A of the objective lens 102 if the particle-optical arrangement is arranged in a multi-beam particle microscope 1. The secondary particle beams 9, for example electron beams, which travel through the secondary particle-optical beam path 11 during the operation of the particle-optical arrangement usually have a lower kinetic energy than the primary particle beams 3. The secondary particles 9 are therefore slower and are deflected more strongly in the first magnetic field region 410 or an orbit radius r_{B} of the orbit described thereby in the homogeneous magnetic field is smaller than a corresponding orbit radius of the faster primary particles 3 or electrons. The exit angle η1 of the secondary particle-optical beam path 11 is therefore in principle an angle different than the entrance angle φ1 of the primary beams 3 of the primary particle-optical beam path 13. The entrance angle φ and the exit angle η1 can be defined by the entrance inclination of the first magnetic field region 410 or the trench G2. In this case, it can be desirable to limit the exit angle η1 of the secondary particle-optical beam path 11 from this first magnetic field region 410 to σ≤35°, such as σ≤25°, for example σ≤15°. This avoids the collection of large aberrations when emerging from the first magnetic field region 410 and additionally creates installation space for possible additional secondary path magnetic field regions in the gap between the first magnetic field region 410 and the second magnetic field region 420. It is moreover desirable for the following to apply to a splitting angle γ through which the primary particle-optical beam path 13 is deflected overall in the first magnetic field region 410 during the operation of the particle-optical arrangement: γ≥14°, such as γ≥16°, for example γ≥18°.

According to a further exemplary embodiment, at least one of the further magnetic field regions of the secondary particle-optical beam path 11 is arranged in a gap between the first magnetic field region 410 and the second magnetic field region 420 of the primary particle-optical beam path 13.

By way of example, the magnet arrangement 400 can have at least two further magnetic field regions in the secondary particle-optical beam path 11 following the passage of the first magnetic field region 410, the at least two further magnetic field regions being configured, in the case of a varying energy of secondary particles whose path forms the second particle-optical beam path 11, to precisely input couple, in terms of offset and angle, the particle-optical axis Z in the secondary beam path 11 into a downstream projection optical unit 200 (see for example FIG. 1). By way of example, the varying energy of the secondary particles 9 may be the result of a modified setting of a landing energy.

According to an exemplary embodiment, the magnet arrangement 400 has at least six further magnetic field regions and/or quadrupole fields in the secondary particle-optical beam path 11 following the passage of the first magnetic field region 410, the at least six further magnetic field regions and/or quadrupole fields being configured, in the case of a varying energy of secondary particles 9 whose path forms the second particle-optical beam path 11, to precisely input couple, in terms of offset and angle, the particle-optical axis Z in the secondary beam path 1 into a downstream projection optical unit 200 (see for example FIG. 1) and additionally enable paraxially stigmatic, paraxially distortion-free and paraxially dispersion-free imaging.

The magnet arrangements 400 according to the disclosure can also be integrated into a multi-beam particle microscope 1, for example into the one depicted schematically in FIG. 1, just like the magnet arrangements 400 according to the prior art.

According to one exemplary embodiment, an imaging of the plurality of the first individual particle beams 3 onto the object plane 101 exhibits substantially no field inclination. Naturally, however, it is also possible to correct other imaging aberrations by way of an appropriate design of the magnet arrangement 400, as has also already been described in greater detail hereinabove. According to one exemplary embodiment, the imaging of the plurality of the first individual particle beams 3 into the object plane 101 is substantially distortion-free overall, and/or the imaging of the first individual particle beams 3 into the object plane 101 is substantially dispersion-free; and/or the incidence locations 5 of the first individual particle beams 3 in the object plane 101 are astigmatic and round. Additionally or alternatively, it is also possible to correct other aberrations within the scope of the particle-optical imaging. Depending on the design, the magnet arrangement 400 according to the disclosure offers appropriate manipulation parameters for correction purposes. The correction may also comprise a correction of a skew of the sample 7 and/or a correction of a focal tilt as a result of a maladjustment of an illumination system/condenser lens system 303.

According to one exemplary embodiment, the imaging of the first individual particle beams 3 into the object plane 101 is field astigmatism-free. Additionally, what may apply is that the sum of all other aberrations of second and third order in the object plane 101 is no more than only 1 nm, such as no more than only 0.5 nm, for example no more than only 0.25 nm. In this case, the stated values are scaled using the used numerical aperture NA and the image field size in the object plane and are determined for a landing energy of 1.5 keV.

### LIST OF REFERENCE SIGNS

1 Multi-beam particle microscope
3 Primary particle beams (individual particle beams)
5 Beam spots, incidence locations
7 Object, sample
9 Secondary particle beams
10 Computer system, controller
11 Secondary particle-optical beam path
13 Primary particle-optical beam path
15 Sample surface
101 Object plane
102 Objective lens
105 Axis
200 Detector system
205 Projection lens system
209 Detection system, particle multi-detector, detection unit
210 Lens
220 Lens
222 Contrast stop
260 Anti-scan
300 Beam generating apparatus
301 Particle source
303 Collimation lens system
305 Multi-aperture arrangement
306 Micro-optics
307 Field lens
308 Field lens
309 Diverging particle beam
323 Beam foci
325 Intermediate image plane
400 Beam splitter, magnet arrangement
405 Drift path
410 Magnetic field region
411 Normal to the particle-optical axis Z in the exit region (primary path)
412 Normal to the particle-optical axis Z in the entrance region (primary path)
415 Normal to the optical axis in the exit region (secondary path)
430 Magnetic field region
431 Normal to the particle-optical axis Z in the exit region
432 Normal to the particle-optical axis Z in the entrance region
450 Magnetic field region
460 Magnetic field region
461 Limb of the beam tube arrangement
462 Limb of the beam tube arrangement
463 Limb of the beam tube arrangement
466 Branching point
470 Magnetic field region
475 Deflector arrangement
471 First deflector
472 Second deflector
481 Plate
482 Plate
490 Beam tube arrangement
491 Plate
492 Plate
495 Shielding wall
500 Scan deflector
600 Displacement stage or positioning device
A Axis, lengthening of the particle-optical axis of the objective lens
Z Particle-optical axis
D1 Plate distance
D2 Plate distance
BE1 Width of the entrance region or trench
BE2 Width of the entrance region or trench
BA1 Width of the exit region or trench
BA2 Width of the exit region or trench
Ri Internal radius of beam tube
r Radius of the multi-image field (mFOV)
z1 . . . z4 z-positions
α1 . . . α4 Inclination angles
β Skew angle
γ Splitting angle
δ Field inclination angle
σ1 . . . σ2 Exit inclination, exit angle (primary particle-optical beam path)
φ1 . . . φ2 Entrance inclination, entrance angle (primary particle-optical beam path)
η1 Exit inclination (secondary particle-optical beam path)
G1 . . . G4 Magnetic field region edge, trench, depression
P1 . . . P4 Point, position
S1 . . . S2 Length of a circular arc

1. A particle-optical arrangement, comprising:
a multi-beam particle generator configured to provide a plurality of first individual particle beams, the particle-optical arrangement configured to provide a primary particle-optical beam path for the plurality of first individual particle beams to an object plane of the multi-particle arrangement, and the particle-optical arrangement configured to provide a secondary particle-optical beam path for a plurality of second individual particle beams emanating from the object plane; and
a magnet arrangement configured to provide:
a first magnetic field region through which the primary and secondary particle-optical beam paths pass to separate the first magnetic field region configured to separate the primary and secondary particle-optical beam paths from each other; and
a second magnetic field region in the primary particle-optical beam path and not in the secondary particle-optical beam path,
wherein:
the second magnetic field region is upstream of the first magnetic field region along the primary particle-optical beam path;
the first magnetic field region and the second magnetic field region configured to deflect the primary particle-optical beam path in different directions;
for each of the first and second magnetic field regions, the magnetic field region comprises an entrance region for the primary particle-optical beam path with an entrance inclination, the entrance inclination being an angle by which an alignment of the entrance region deviates from a normal to a particle-optical axis of the primary particle-optical beam path;
for each of the first and second magnetic field regions, the magnetic field region comprises an exit region for the primary particle-optical beam path with an exit inclination, the exit inclination being an angle by which an alignment of the exit region deviates from the normal to the particle-optical axis of the primary particle-optical beam path; and
the exit inclination of the first magnetic field region deviates from 0°.

2. The particle-optical arrangement of claim 1, wherein the exit inclination of the first magnetic field region has an absolute value of at least 0.5°.

3. The particle-optical arrangement of claim 1, wherein the exit inclination of the first magnetic field region has an absolute value of at most 10°.

4. The particle-optical arrangement of claim 1, wherein the entrance inclination of the first magnetic field region differs from 0°.

5. The particle-optical arrangement of claim 1, wherein:
the entrance inclination of the second magnetic field region has an absolute value of at most 10°; and/or
the exit inclination of the second magnetic field region has an absolute value of at most 10°.

6. The particle-optical arrangement of claim 1, further comprising a deflector arrangement upstream of the second magnetic field region along the primary particle-optical beam path, wherein the deflector arrangement is configured to set:
an entrance direction of the primary particle-optical beam path into the second magnetic field region and thus the entrance inclination to an accuracy of at least +/−0.1; and/or
an entrance location of the primary particle-optical beam path into the second magnetic field region to an accuracy of at least +/−0.3 millimeter.

7. The particle-optical arrangement of claim 1, wherein:
a direction of the magnetic field in the first magnetic field region is substantially orthogonal to an optical axis of the primary particle-optical beam path;
the magnetic field in the first magnetic field region is substantially homogeneous;
a direction of the magnetic field in the second magnetic field region is substantially orthogonal to the optical axis of the primary particle-optical beam path; and
the magnetic field in the second magnetic field region is substantially homogeneous.

8. (canceled)

9. (canceled)

10. The particle-optical arrangement of claim 1, wherein a drift region is free from magnetic fields, and the drift region is in the primary particle-optical beam path between the first and second magnetic field regions.

11. (canceled)

12. The particle-optical arrangement of claim 1, wherein:
the magnetic arrangement has an overall height that is distance between an entrance point of the primary particle-optical beam path into the second magnetic field region and an exit point of the primary particle-optical beam path from the first magnetic field region; and
the overall height of the magnetic arrangement is at most one centimeter.

13. The particle-optical arrangement of claim 1, wherein:
the first magnetic field region comprises two plates that are parallel;
the two plates are a distance D1 from one each other;
between the two plates, a homogeneous magnetic field is generated during operation of the particle-optical arrangement; and
at least one of the following holds:
the entrance region of the first magnetic field region is linear, the entrance region of the first magnetic field region has a width BE1, and BE1/D1 is at least 2.5; and
the exit region of the first magnetic field region is linear, the exit region of the first magnetic field region has a width BA1, and BA1/D1 is at least 2.5.

14. The particle-optical arrangement of claim 1, wherein:
the second magnetic field region comprises two plates parallel to each other;
the two plates are a distance D2 from one each other;
between the two plates, a homogeneous magnetic field is generated during operation of the particle-optical arrangement; and
at least one of the following holds:
the entrance region of the second magnetic field region is linear, the entrance region of the second magnetic field region has a width BE2, and BE2/D2 is at least 2.5; and/or the exit region of the second magnetic field region is linear, the exit region of the second magnetic field region is linear has a width BA2, and BA/D2 is at least 2.5.

15. The particle-optical arrangement of claim 1, wherein:
the magnet arrangement comprises a beam tube arrangement within which the primary particle-optical beam path passes within the magnet arrangement;
the beam tube arrangement has a fill factor within the magnet arrangement during operation of the particle-optical arrangement that is at most 55%.

16. The particle-optical arrangement of claim 1,
wherein the following relation applies to a splitting angle γ through which the primary particle-optical beam path is deflected overall in the first magnetic field region during operation of the particle-optical arrangement: γ≥14°, for example γ≥16° or γ≥18°.

17. The particle-optical arrangement of claim 1, wherein an exit angle of the secondary particle-optical beam path from this first magnetic field region is at most 35°.

18. The particle-optical arrangement of claim 1, wherein the magnet arrangement comprises a third magnetic field region, the third magnetic field region being in the secondary particle-optical beam path.

19. The particle-optical arrangement of claim 1, further comprising a projection optical unit, wherein:
the magnet arrangement comprises third and fourth magnetic field regions;
each of the third and fourth magnetic field regions is in the secondary beam path following the passage of the first magnetic field region; and
the third and fourth magnetic field regions are configured so that, when secondary particles whose path forms the second particle-optical beam path have a varying energy, the third and fourth magnetic field regions precisely input couple, in terms of offset and angle, the particle-optical axis in the secondary beam path into the projection optical unit.

20. The particle-optical arrangement of claim 1, further comprising a projection optical unit, wherein:
the magnet arrangement comprises six further magnetic field regions and/or quadrupole fields in the secondary beam path following the passage of the first magnetic field region;
the at least six further magnetic field regions and/or quadrupole fields are configured so that, when secondary particles whose path forms the second particle-optical beam path have varying energy, the six further magnetic field and/or quadrupole fields precisely input couple, in terms of offset and angle, the particle-optical axis in the secondary beam path into the projection optical unit and additionally enable paraxially stigmatic, paraxially distortion-free and paraxially dispersion-free imaging.

21. The particle-optical arrangement of claim 1, wherein:
the magnet arrangement comprises a third magnetic field region;
the third magnetic field region being in the secondary particle-optical beam path;
the third magnetic field regions is in a gap along the primary particle-optical beam path between the first and second magnetic field regions.

22. The particle-optical arrangement of claim 1, further comprising a magnetic shielding wall, wherein:
the magnet arrangement comprises a third magnetic field region;
the third magnetic field region being in the secondary particle-optical beam path; and
the magnetic shielding is between least one of the magnetic field regions of the primary particle-optical beam path and at least one of the magnetic field regions of the secondary particle-optical beam path.

23. The particle-optical arrangement of claim 1, wherein:
the particle-optical arrangement is a multi-beam particle microscope;
the multi-beam particle generator is configured to generate a first field of a plurality of charged first individual particle beams; and
the particle-optical arrangement further comprises:
a first particle-optical unit comprising the primary particle-optical beam path, the first particle-optical unit configured to image the first individual particle beams onto the object plane so that the first individual particle beams impinge on an object at incidence locations in the object plane, the first particle-optical unit configured to generate a second field;
a detection unit comprising a plurality of detection regions defining a third field;
a second particle-optical unit comprising the secondary particle-optical beam path, the second particle-optical unit configured to image second individual particle beams, emanating from the incidence locations in the second field, onto the third field; and
a magnetic and/or electrostatic objective lens configured to have both the first and the second individual particle beams pass therethrough;
the magnet arrangement is in the primary particle-optical beam path between the multi-beam particle generator and the objective lens; and
the magnet arrangement is in the secondary particle-optical beam path between the objective lens and the detection unit.

24.-29. (canceled)
